(19) United States
(12) Patent Application Publication
(10) Pub. No.: US 2019/0089349 A1
(43) Pub. Date: Mar. 21, 2019

(54) SWITCHING CIRCUIT

(71) Applicant: TOYOTA JIDOSHA KABUSHIKI KAISHA, Toyota-shi (JP)

(72) Inventors: Ken TOSHIYUKI, Nisshin-shi (JP); Shun ITO, Toyota-shi (JP); Takeshi HIRANO, Okazaki-shi (JP); Tomotaka SUZUKI, Kariya-shi (JP)

(73) Assignee: TOYOTA JIDOSHA KABUSHIKI KAISHA, Toyota-shi (JP)

(21) Appl. No.: 16/130,951

(22) Filed: Sep. 13, 2018

(30) Foreign Application Priority Data
Sep. 15, 2017 (JP) 2017-177996

(51) Int. Cl. H03K 17/16; H03K 17/0812; H03K 17/12; H03K 17/567; H03K 17/687

(52) U.S. Cl. CPC H03K 17/168; H03K 17/08128; H03K 17/127; H03K 17/687; H03K 17/567; H03K 17/08122; H03K 17/162

(57) ABSTRACT

A switching circuit may include a first switching element, a second switching element, a high potential wiring, a low potential wiring, a gate wiring connecting the first gate terminal and the second gate terminal, a driving circuit connected to the low potential wiring and the gate wiring, a first common-mode choke coil including a first coil and a second coil. The first coil may be interposed on the gate wiring between the driving circuit and the first gate terminal, the second coil may be interposed on the low potential wiring between the driving circuit and the first low potential terminal, and the first common-mode choke coil may be configured such that a direction passing through the first coil from the driving circuit toward the first gate terminal and a direction passing through the second coil from the driving circuit toward the first low potential terminal are common-mode.

### TECHNICAL FIELD

The disclosure herewith relates to a switching circuit.

### BACKGROUND

In a power control circuit such as an inverter and a converter, when two switching elements connected in parallel are simultaneously switched, a current flowing through each of the switching elements may strongly vibrates (oscillates). Such a phenomenon is induced by an imbalance between currents flowing through two switching elements due to manufacturing errors in the switching elements, a difference in switching timing, and the like. The imbalance between currents results in a potential difference between low potential terminals of the two switching elements due to parasitic inductance of a wiring connected to each of the low potential terminals of the two switching elements. This causes oscillations in the switching elements.

A switching circuit 100 in FIG. 9 is used as an example to describe an oscillation phenomenon. The switching circuit 100 includes two switching elements 111, 112. The switching elements 111, 112 are connected in parallel between a high potential wiring 192 and a low potential wiring 194. Freewheeling diodes 121, 122 are connected in inverse parallel to the two switching elements 111, 112, respectively. The switching elements 111, 112 are, for example, IGBTs (Insulated Gate Bipolar Transistors). The switching element 111 includes a high potential terminal 111c, a low potential terminal 111e, and a gate terminal 111g. The switching element 112 includes a high potential terminal 112c, a low potential terminal 112e, and a gate terminal 112g. The gate terminal 111g and the gate terminal 112g are connected by a gate wiring 180. A driving circuit 210 that controls a potential of the gate terminal 111g and a potential of the gate terminal 112g is connected to the gate wiring 180. Moreover, the driving circuit 210 is connected to the low potential wiring 194. The high potential terminal 111c and the high potential terminal 112c are connected to the high potential wiring 192. The low potential terminal 111e and the low potential terminal 112e are connected to the low potential wiring 194.

Here, a state is assumed in which both of the switching elements 111, 112 are off, and are then be switched from off to on by a driving signal being supplied from the driving circuit 210 to the switching elements 111, 112. Initially, the supply of the driving signal from the driving circuit 210 raises both of the potentials of the gate terminals 111g, 112g. When each of the potentials of the gate terminals 111g, 112g of the switching elements 111, 112 exceeds its threshold value, both of the switching elements 111, 112 are brought into an on state, and currents I1, I2 shown in FIG. 9 start flowing. At this time, an imbalance between the current I1 flowing through the switching element 111 and the current I2 flowing through the switching element 112 occurs due to manufacturing errors in the switching elements 111, 112 and the like. Here, a case where a relation I1<I2 holds will be considered. When the current I1 flows from the low potential terminal 111e to the low potential wiring 194, parasitic inductance of the low potential wiring 194 generates an electromotive force. Thus, a potential Ve1 of the low potential terminal 111e becomes higher than that at a point 194a on the low potential wiring 194. Similarly, when the current I2 flows from the low potential terminal 112e to the low potential wiring 194, parasitic inductance of the low potential wiring 194 generates an electromotive force. Thus, a potential Ve2 of the low potential terminal 112e becomes higher than that at the point 194a on the low potential wiring 194. Since the current I2 is larger than the current I1, the potential Ve2 of the low potential terminal 112e becomes higher than the potential Ve1 of the low potential terminal 111e. Due to this, a potential Vg2 of the gate terminal 112g of the switching element 112 becomes higher than a potential Vg1 of the gate terminal 111g of the switching element 111. Then, a current flows through the gate wiring 180 from the gate terminal 112g toward the gate terminal 111g. Consequently, the potential Vg1 rises and the potential Vg2 falls, resulting in an increase in the current I1 flowing through the switching element 111 and a decrease in the current I2 flowing through the switching element 112. Consequently, due to an influence of the electromotive force of the parasitic inductance of the low potential wiring 194, the potential Ve1 of the low potential terminal 111e becomes higher than the potential Ve2 of the low potential terminal 112e. Due to this, the potential Vg1 of the gate terminal 111g of the switching element 111 becomes higher than the potential Vg2 of the gate terminal 112g of the switching element 112. Then, a current flows through the gate wiring 180 from the gate terminal 111g toward the gate terminal 112g, resulting in the potential Vg2 of the gate terminal 112g becoming higher than the potential Vg1 of the gate terminal 111g. As a result, the current I2 flowing through the switching element 112 becomes larger again than the current I1 flowing through the switching element 111. As such, the imbalance between the currents I1, I2 respectively flowing through the two switching elements 111, 112 causes repetitive rises and falls in the potentials Vg1, Vg2, and thereby oscillations in the currents I1, I2 occur.

Japanese Patent Application Publication No. 2017-028956 describes a switching circuit that includes two switching elements connected in parallel to each other. In this switching circuit, in a process of turning on both of the two switching elements, a standby period is provided during which one switching element is brought into an on state and the other switching element is maintained in an off state. After the standby period has elapsed, the off-state switching element is brought into the on state. According to the technology in Japanese Patent Application Publication No. 2017-028956, oscillations in the switching elements can be suppressed.

### SUMMARY

The technology in Japanese Patent Application Publication No. 2017-028956 provides the standby period during which one of the switching elements is maintained in the off state when the other switching element is turned on. Accordingly, a large current flows through the on-state switching element during the standby period. Therefore, there is a problem that a large load may be imposed on the on-state switching element. The disclosure herein provides a technology capable of suppressing oscillations in a plurality of switching elements connected in parallel by adopting a configuration different from that of Japanese Patent Application Publication No. 2017-028956.

A switching circuit disclosed herein may comprise: a first switching element including a first high potential terminal, a first low potential terminal, and a first gate terminal; a second switching element including a second high potential terminal, a second low potential terminal, and a second gate terminal; a high potential wiring connecting the first high potential terminal and the second high potential terminal; a low potential wiring connecting the first low potential terminal and the second low potential terminal; a gate wiring connecting the first gate terminal and the second gate terminal; a driving circuit connected to the low potential wiring and the gate wiring, and configured to control a potential of the first gate terminal and a potential of the second gate terminal; and a first common-mode choke coil including a first coil and a second coil. The first coil may be interposed on the gate wiring between the driving circuit and the first gate terminal, the second coil may be interposed on the low potential wiring between the driving circuit and the first low potential terminal, and the first common-mode choke coil may be configured such that a direction passing through the first coil from the driving circuit toward the first gate terminal and a direction passing through the second coil from the driving circuit toward the first low potential terminal are common mode.

It should be noted, as a potential of the high potential wiring and a potential of the low potential wiring fluctuate, the potential of the low potential wiring may become momentarily higher than the potential of the high potential wiring. In other words, the high potential wiring means a wiring that has an average potential higher than that of the low potential wiring.

This switching circuit includes the first common-mode choke coil. When current(s) in a same direction (hereinafter referred to as common-mode current) flow through the first and second coils, magnetic fluxes generated in the first and second coils are added together. As a result, the first common-mode choke coil functions as an inductor. On the other hand, when current(s) in reverse directions (hereinafter referred to as differential-mode current)flow through the first and second coils, magnetic fluxes generated in the first and second coils cancel each other out. As a result, the first common-mode choke coil does not function as an inductor.

Description will be made on an operation of the above switching circuit in a case where the first and second switching elements are switched from an off state to an on state. The driving circuit charges the first gate terminal of the first switching element to turn on the first switching element, and charges the second gate terminal of the second switching element to turn on the second switching element. When the first switching element is to be turned on, a gate current flows from the first low potential terminal of the first switching element toward the first gate terminal via the driving circuit such that the first gate terminal is charged. At this time, the gate current flows through the second coil in a direction from the first low potential terminal toward the driving circuit as well as flows through the first coil in a direction from the driving circuit toward the first gate terminal. In other words, the gate current is a differential-mode current. Therefore, the first and second coils do not function as inductors, and the first gate terminal of the first switching element can be charged quickly.

When the first and second switching elements are brought into the on state, a current imbalance may occur. If a current flowing through the second switching element is larger than a current flowing through the first switching element, a potential of the second low potential terminal becomes higher than a potential of the first low potential terminal due to an electromotive force of parasitic inductance of the low potential wiring. Accordingly, a current flows through the low potential wiring in a direction from the second low potential terminal toward the first low potential terminal. Thus, the current flows through the second coil in a direction from the driving circuit toward the first low potential terminal. Moreover, when the potential of the second low potential terminal becomes higher than the potential of the first low potential terminal, the potential of the second gate terminal becomes higher than the potential of the first gate terminal. Then, a current flows through the gate wiring in a direction from the second gate terminal toward the first gate terminal. In other words, the current flows through the first coil in the direction from the driving circuit toward the first low potential terminal. As such, the currents flowing through the first coil (the gate wiring) and the second coil (the low potential wiring) are common-mode currents. Accordingly, the first and second coils function as inductors, and suppress the currents that flow through the gate wiring and the low potential wiring. Therefore, oscillations can be suppressed. Moreover, also in a case where the current flowing through the first switching element is larger than the current flowing through the second switching element, the currents flowing through the first and second coils are common-mode currents, and oscillations can be suppressed similarly.

As described above, the first common-mode choke coil does not function as an inductor when charging the first gate terminal, and thus can charge the first gate terminal quickly. On the other hand, if a current imbalance occurs when the first and second switching elements are brought into the on state, the first common-mode choke coil functions as an inductor, and suppresses oscillations. According to this switching circuit, oscillations in the switching elements can be suppressed without decreasing switching speed of the switching elements.

### BRIEF DESCRIPTION OF THE DRAWINGS

FIG. 1 is a circuit diagram of an inverter 90;

FIG. 2 is a circuit diagram of a switching circuit 10 according to a first embodiment (illustrating current paths when each of switching elements is charged);

FIG. 3 is the circuit diagram of the switching circuit 10 according to the first embodiment (illustrating current paths when a current imbalance occurs between the switching elements);

FIG. 4 is a circuit diagram of a switching circuit 10a according to a second embodiment;

FIG. 5 is a circuit diagram illustrating a part of the switching circuit 10a according to the second embodiment;

FIG. 6 is a circuit diagram of a switching circuit 10b according to a third embodiment;

FIG. 7 is a circuit diagram of a switching circuit 10c according to a fourth embodiment;

FIG. 8 is a circuit diagram of a switching circuit according to a variant; and

FIG. 9 is a circuit diagram of a switching circuit 100 according to a comparative example.

### DETAILED DESCRIPTION

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved switching circuit, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### First Embodiment

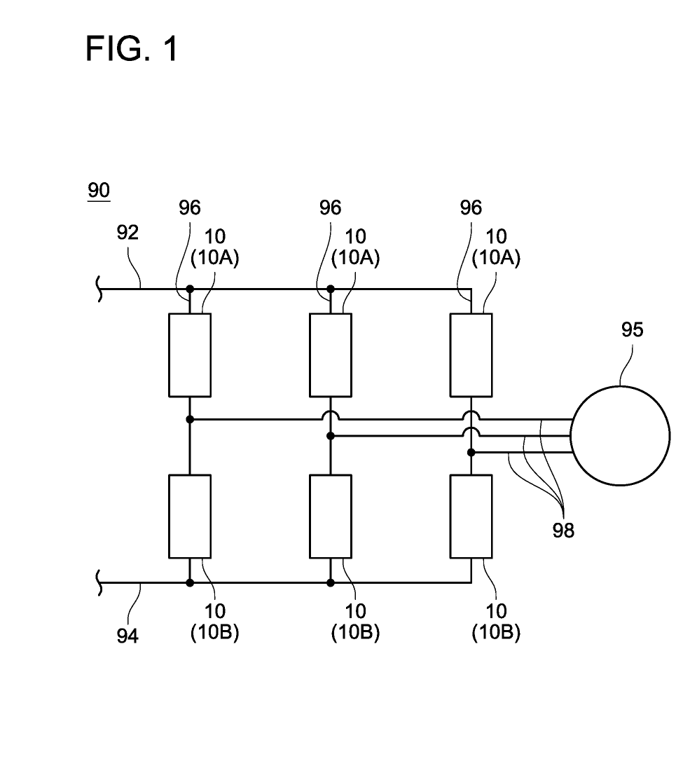

With reference to the drawings, a switching circuit 10 of a first embodiment will be described. FIG. 1 illustrates a circuit diagram of an inverter 90 to which the switching circuit 10 of the present embodiment is applied. The inverter 90 includes a positive-side power source wiring 92 and a negative-side power source wiring 94. A direct-current (DC) voltage is applied between the positive-side power source wiring 92 and the negative-side power source wiring 94 by a DC power source, which is not shown. The DC voltage is applied such that the positive-side power source wiring 92 has a potential higher than that of the negative-side power source wiring 94. The inverter 90 converts this DC power into alternating-current (AC) power, and supplies the AC power to a motor 95.

Three pairs of circuits, each of which includes two switching circuits 10 connected in series by a connection wiring 96, are provided between the positive-side power source wiring 92 and the negative-side power source wiring 94. It should be noted that each of the switching circuits 10 on an upper arm (on a positive-side power source wiring 92's side) is a switching circuit 10A, and each of the switching circuits 10 on a lower arm (on a negative-side power source wiring 94's side) is a switching circuit 10B. Configurations of the switching circuits 10 are mutually identical. The inverter 90 includes three intermediate wirings 98. Each of the intermediate wirings 98 has one end thereof connected to its corresponding one of the connection wirings 96 between the two switching circuits 10 connected in series. Each of the intermediate wirings 98 has the other end thereof connected to the motor 95. The switching circuits 10 switch the connecting wirings 96 between on and off to convert the DC voltage applied between the positive-side power source wiring 92 and the negative-side power source wiring 94 into a three-phase AC voltage, and the converted three-phase AC voltage is outputted to the three intermediate wirings 98. The three-phase AC voltage is supplied to the motor 95 via the three intermediate wirings 98.

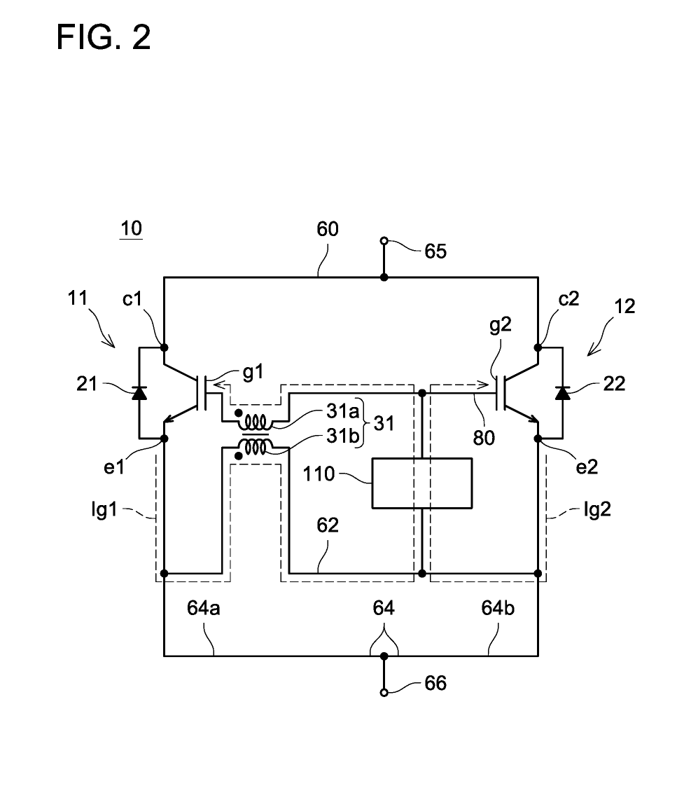

Next, the configuration of the switching circuits 10 will be described in detail. It should be noted, since the configuration is mutually identical among the switching circuits 10, the configuration of one of the switching circuits 10 will be described. FIG. 2 shows a circuit diagram of each of the switching circuits 10. The switching circuit 10 includes a first switching element 11 and a second switching element 12. In the present embodiment, each of the switching elements 11, 12 is an IGBT (Insulated Gate Bipolar Transistor). A high potential wiring 60 connects a collector terminal cl of the first switching element 11 and a collector terminal c2 of the second switching element 12 to each other. The high potential wiring 60 is connected to a wiring 65 that extends to a circuit on an upstream side. In other words, in the switching circuit 10A on an upper-arm side, the high potential wiring 60 is connected to the positive-side power source wiring 92. In the switching circuit 10B on a lower-arm side, the high potential wiring 60 is connected to the intermediate wiring 98 and the switching circuit 10A. A first low potential wiring 62 connects an emitter terminal el of the first switching element 11 and an emitter terminal e2 of the second switching element 12. In other words, the first switching element 11 and the second switching element 12 are connected in parallel. Furthermore, a second low potential wiring 64 also connects the emitter terminal el of the first switching element 11 and the emitter terminal e2 of the second switching element 12 to each other. The second low potential wiring 64 is connected to a wiring 66 that extends to a circuit on a downstream side. In other words, in the switching circuit 10A on the upper-arm side, the second low potential wiring 64 is connected to the intermediate wiring 98 and the switching circuit 10B. In the switching circuit 10B on the lower-arm side, the second low potential wiring 64 is connected to the negative-side power source wiring 94. A gate wiring 80 connects a gate terminal g1 of the first switching element 11 and a gate terminal g2 of the second switching element 12. A diode 21 is connected in inverse parallel to the first switching element 11. In other words, the diode 21 has its anode connected to the emitter terminal e1, and its cathode connected to the collector terminal c1. A diode 22 is connected in inverse parallel to the second switching element 12. In other words, the diode 22 has its anode connected to the emitter terminal e2, and its cathode connected to the collector terminal c2.

As shown in FIG. 2, the switching circuit 10 includes a driving circuit 110 and a first common-mode choke coil 31.

The driving circuit 110 is connected to the gate wiring 80 and the first low potential wiring 62. The driving circuit 110 controls a potential of the gate terminal g1 of the first switching element 11, and a potential of the gate terminal g2 of the second switching element 12. The gate terminal g1 of the first switching element 11 and the gate terminal g2 of the second switching element 12 are supplied with a common driving signal from the driving circuit 110. Therefore, the first switching element 11 and the second switching element 12 are switched at approximately a same timing. Accordingly, a current with a total value of current capacities of the first switching element 11 and the second switching element 12 can flow through the parallel circuit of the first switching element 11 and the second switching element 12.

The first common-mode choke coil 31 includes a first coil 31a and a second coil 31b. The first coil 31a is interposed on the gate wiring 80 between the driving circuit 110 and the gate terminal g1. The second coil 31b is interposed on the first low potential wiring 62 between the driving circuit 110 and the emitter terminal e1. The first common-mode choke coil 31 is configured such that a direction passing through the first coil 31a from the driving circuit 110 toward the gate terminal g1 and a direction passing through the second coil 31b from the driving circuit 110 toward the emitter terminal el are common mode. The first common-mode choke coil 31 is configured such that the first coil 31a and the second coil 31b are of subtractive polarity.

Next, an on operation of the switching circuit 10 will be described. In an off state of the switching circuit 10, the driving circuit 110 maintains the gate wiring 80 at the same potential as that of the first low potential wiring 62. In the on operation, the driving circuit 110 raises the potential of the gate wiring 80 to a potential higher than the potential of the first low potential wiring 62. At this time, a gate current Ig1 flows from the emitter terminal el toward the gate terminal g1 via the first low potential wiring 62, the driving circuit 110, and the gate wiring 80, and the gate terminal g1 is charged. The first switching element 11 is turned on by the gate terminal g1 being charged. At the same time, a gate current Ig2 flows from the emitter terminal e2 toward the gate terminal g2 via the first low potential wiring 62, the driving circuit 110, and the gate wiring 80, and the gate terminal g2 is charged. The gate current Ig1 of the first switching element 11 flows through the first coil 31a and the second coil 31b. The gate current Ig1 flows through the second coil 31b from a first switching element 11's side toward a driving circuit 110's side as well as flows through the first coil 31a from the driving circuit 110's side toward the first switching element 11's side. In other words, the gate current Ig1 flows through the first common-mode choke coil 31 in a differential mode. Since a value of the current flowing through the first coil 31a and a value of the current flowing through the second coil 31b are approximately equal, magnetic fluxes generated in the first coil 31a and in the second coil 31b cancel each other out. Thus, the first common-mode choke coil 31 does not function as an inductor, and the gate terminal g1 and the gate terminal g2 are charged quickly. When the potential of the gate terminal g1 and the potential of the gate terminal g2 each exceed their threshold values, the first switching element 11 and the second switching element 12 are brought into the on state, and a main current starts flowing through each of the switching elements 11, 12. As such, in the case where the gate terminal g1 of the first switching element 11 is to be charged, the first common-mode choke coil 31 does not function as an inductor, so the gate terminal g1 is charged quickly. Accordingly, the first switching element 11 can be switched at a high speed equal to that of the second switching element 12. Further, in this case, a loss is hardly caused in the first common-mode choke coil 31, and hence a loss at switching can be reduced.

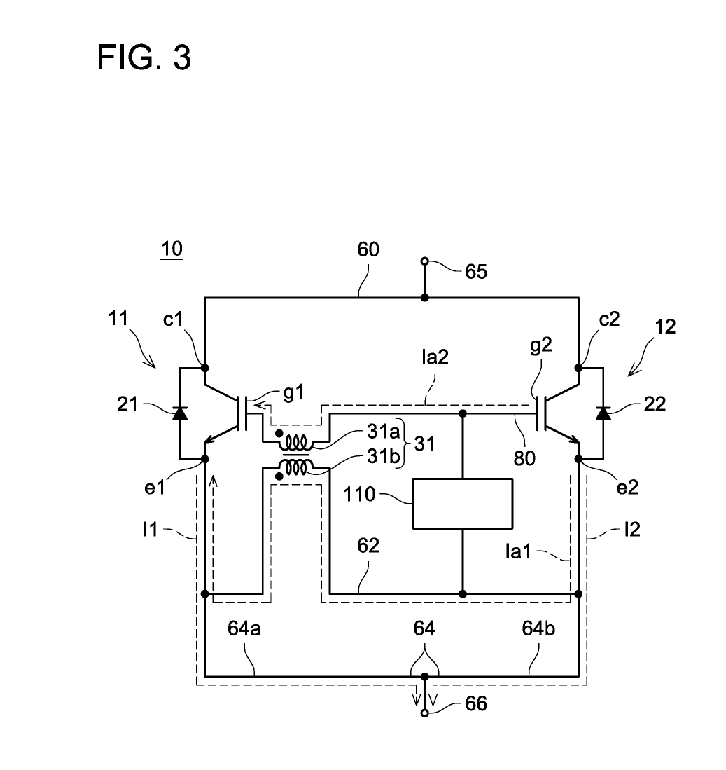

Next, description will be made on an operation in a case where a current imbalance occurs immediately after each of the switching elements 11, 12 is turned on. As shown in FIG. 3, a current I1 flows through the first switching element 11 when the first switching element 11 is turned on, and a current I2 flows through the second switching element 12 when the second switching element 12 is turned on. The current I1 flows to the wiring 66 on the downstream side via a portion of the second low potential wiring 64 on the first switching element 11's side (hereinafter referred to as a wiring 64a). The current I2 flows to the wiring 66 on the downstream side via a portion of the second low potential wiring 64 on a second switching element 12's side (hereinafter referred to as a wiring 64b). Immediately after each of the switching elements 11, 12 is turned on, the current I1 and the current I2 may be imbalanced because of errors in properties of the switching elements 11, 12, and the like.

Description will be made on a case where the current I2 is larger than the current I1. When the current I1 flows, parasitic inductance of the wiring 64a generates an electromotive force. Therefore, a potential Ve1 of the emitter terminal el of the first switching element 11 becomes higher than a potential of the wiring 66 on the downstream side. Similarly, when the current I2 flows, parasitic inductance of the wiring 64b generates an electromotive force. Therefore, a potential Ve2 of the emitter terminal e2 of the second switching element 12 becomes higher than the potential of the wiring 66 on the downstream side. If the current I2 is larger than the current I1, the potential Ve2 is higher than the potential Ve1. Accordingly, a current Ia1 flows through the first low potential wiring 62 from the emitter terminal e2 toward the emitter terminal e1. Moreover, when the potential Ve1 of the emitter terminal e1 rises, a potential Vg1 of the gate terminal g1 also rises because of capacitive coupling. When the potential Ve2 of the emitter terminal e2 rises, a potential Vg2 of the gate terminal g2 also rises because of capacitive coupling. Since an amount of rise in the potential Ve2 is larger than an amount of rise in the potential Ve1, an amount of rise in the potential Vg2 is larger than an amount of rise in the potential Vg1. Therefore, the potential Vg2 becomes higher than the potential Vg1. Then, a current Ia2 flows through the gate wiring 80 in a direction from the gate terminal g2 toward the gate terminal g1. The current Ia1 flows through the second coil 31b from the driving circuit 110's side toward the first switching element 11's side. The current Ia2 flows through the first coil 31a from the driving circuit 110's side toward the first switching element 11's side. In other words, the currents Ia1, Ia2 flow through the first common-mode choke coil 31 in a common mode. As such, in the case where a current imbalance occurs, the currents flowing through the first coil 31a and the second coil 31b are common-mode currents. Accordingly, magnetic fluxes generated by the currents flowing through the first coil 31a and the second coil 31b are added together. As a result, the first common-mode choke coil 31 functions as an inductor, and suppresses the current Ia1 and the current Ia2. As a result, the currents Ia1, Ia2 are attenuated in a short time, and the potential Vg1 of the gate terminal g1 and the potential Vg2 of the gate terminal g2 become approximately the same. Thus, the current I1 and the current I2 come to have an approximately same magnitude, so the current imbalance is eliminated. Accordingly, in this switching circuit 10, an oscillation phenomenon is less likely to occur when a current imbalance occurs.

Moreover, if the current I1 is larger than the current I2 immediately after each of the switching elements 11, 12 is turned on, the current Ia1 and the current Ia2 flow in a reverse direction relative to the direction in FIG. 3. In this case as well, the currents flow through the first common-mode choke coil 31 in the common mode, so the first common-mode choke coil 31 functions as an inductor. Accordingly, the currents Ia1, Ia2 are attenuated in a short time, and the potential Vg1 of the gate terminal g1 and the potential Vg2 of the gate terminal g2 become approximately the same. Thus, in this case as well, the oscillation phenomenon is less likely to occur.

Next, an off operation of the switching circuit 10 will be described. In the off operation, the driving circuit 110 lowers the potential of the gate wiring 80 to the same potential as that of the first low potential wiring 62. At this time, the currents Ig1, Ig2 respectively flow in reverse directions relative to their directions in FIG. 2. Due to this, the gate terminals g1, g2 are discharged, and each of the switching elements 11, 12 is turned off. In this case, the gate current Ig1 flows through the first common-mode choke coil 31 in the differential mode. Accordingly, in the off operation, the first common-mode choke coil 31 does not function as an inductor, so the gate terminal g1 is discharged quickly. Accordingly, the first switching element 11 can be switched at a high speed same as that of the second switching element 12. In this case, in addition, a loss is hardly caused in the first common-mode choke coil 31, and hence a loss at switching can be reduced.

As mentioned above, the first common-mode choke coil 31 does not function as an inductor for the charge current and the discharge current of the gate terminals g1, g2 of the switching elements 11, 12, whereas the first common-mode choke coil 31 functions as an inductor for the currents Ia1, Ia2 flowing when the current imbalance occurs. According to the switching circuit 10 of the present embodiment, it is possible to suppress the oscillation phenomenon while suppressing a decrease in switching speed. In the switching circuit 10 of the present embodiment, it is also possible to similarly suppress the oscillation phenomenon that occurs when each of the first switching element 11 and the second switching element 12 is switched from the on state to the off state.

### Second Embodiment

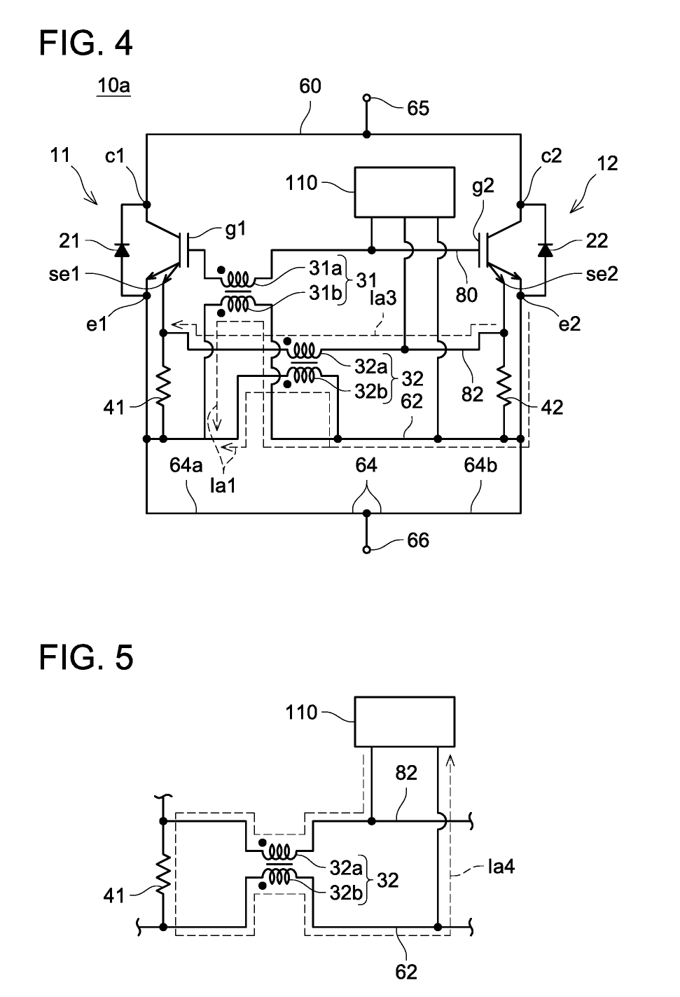

Next, with reference to FIG. 4, a switching circuit 10a of a second embodiment will be described. It should be noted that description on configurations of the switching circuit 10a of the second embodiment that are common to the configurations of the switching circuit 10 of the first embodiment will be omitted. In the switching circuit 10a, in addition to the emitter terminal e1 through which the main current flows, the first switching element 11 further includes a sense emitter terminal se1 through which a current smaller than the main current flows. In addition to the emitter terminal e2 through which the main current flows, the second switching element 12 further includes a sense emitter terminal se2 through which a current smaller than the main current flows. Moreover, the switching circuit 10a further includes a sense wiring 82, a second common-mode choke coil 32, and current sense resistors 41, 42.

The sense emitter terminal se1 is connected to the first low potential wiring 62 via the current sense resistor 41. A small current that is approximately proportional to the main current flowing through the emitter terminal e1 flows through the sense emitter terminal se1. This small current flows from the sense emitter terminal se1 toward the second low potential wiring 64 via the current sense resistor 41. Accordingly, a potential of the sense emitter terminal se1 is proportional to the current that flows through the sense emitter terminal se1 (i.e., current that flows through the current sense resistor 41). Accordingly, the potential of the sense emitter terminal se1 is approximately proportional to the main current that flows through the emitter terminal e1 (i.e., the main current that flows through the first switching element 11). Therefore, the main current that flows through the first switching element 11 can be detected by detecting the potential of the sense emitter terminal se1. The sense emitter terminal se2 is connected to the first low potential wiring 62 via the current sense resistor 42. The main current that flows through the second switching element 12 can be detected by detecting a potential of the sense emitter terminal se2.

The sense wiring 82 connects the sense emitter terminal se1 of the first switching element 11 and the sense emitter terminal se2 of the second switching element 12. Moreover, the sense wiring 82 is connected to the driving circuit 110.

The second common-mode choke coil 32 includes a third coil 32a and a fourth coil 32b. The third coil 32a is interposed on the sense wiring 82 between the driving circuit 110 and the sense emitter terminal se1. The fourth coil 32b is interposed on the first low potential wiring 62 between the driving circuit 110 and the emitter terminal e1. More specifically, the fourth coil 32b is connected in parallel to the second coil 31b of the first common-mode choke coil 31 between the driving circuit 110 and the emitter terminal e1. The second common-mode choke coil 32 is configured such that a direction passing through the third coil 32a from the driving circuit 110 toward the sense emitter terminal se1 and a direction passing through the fourth coil 32b from the driving circuit 110 toward the emitter terminal e1 are common mode. The second common-mode choke coil 32 is configured such that the third coil 32a and the fourth coil 32b are of subtractive polarity.

In the switching circuit 10a of the second embodiment as well, the first common-mode choke coil 31 functions as in the first embodiment. In the switching circuit 10a of the second embodiment, an imbalance occurs also between sense currents due to the imbalance between the main currents that respectively flow through the switching elements 11, 12. If the main current 12 flowing through the second switching element 12 is larger than the main current I1 flowing through the first switching element 11, in other words, if a sense current flowing through the sense emitter terminal se2 is larger than a sense current flowing through the sense emitter terminal se1, the potential of the sense emitter terminal se2 becomes higher than the potential of the sense emitter terminal se1. Due to this, a current Ia3 flows through the sense wiring 82 from the sense emitter terminal se2 toward the sense emitter terminal se1. When the current Ia3 flows between the sense emitter terminal se1 and the sense emitter terminal se2 in a to-and-fro (vibrating) manner, the oscillation phenomenon occurs. However, in the switching circuit 10a of the second embodiment, the second common-mode choke coil 32 suppresses the oscillation phenomenon resulting from the current Ia3, as described below.

In the switching circuit 10a of the second embodiment, when the current Ia3 flows, the current Ia1 flows through the first low potential wiring 62 as in the first embodiment. In the second embodiment, as shown in FIG. 4, the current Ia1 diverges and flows through the second coil 31b and the fourth coil 32b. As is clear from FIG. 4, the currents Ia1, Ia3 flow through the second common-mode choke coil 32 in the common mode. Accordingly, magnetic fluxes generated by the currents that flow through the third coil 32a and the fourth coil 32b are added together. As a result, the second common-mode choke coil 32 functions as an inductor, and suppresses the currents Ia1 and Ia3. It is thereby possible to suppress fluctuations in the potentials of the gate terminal g1 and the gate terminal g2 that are resulted from vibrations in the current Ia3. In other words, the oscillation phenomenon can be suppressed.

Moreover, as shown in FIG. 5, when the sense current is to be detected, a current Ia4 flows through the third coil 32a and the fourth coil 32b in the differential mode. The driving circuit 110 detects the sense current based on the current Ia4. Therefore, the third coil 32a and the fourth coil 32b do not function as inductors, and the sense current can be detected suitably.

As such, according to the switching circuit 10a, since the second common-mode choke coil 32 functions as an inductor when a current imbalance occurs, oscillations can be suppressed suitably. Moreover, since the second common-mode choke coil 32 does not function as an inductor at the detection of a sense current, a loss can be suppressed.

### Third Embodiment

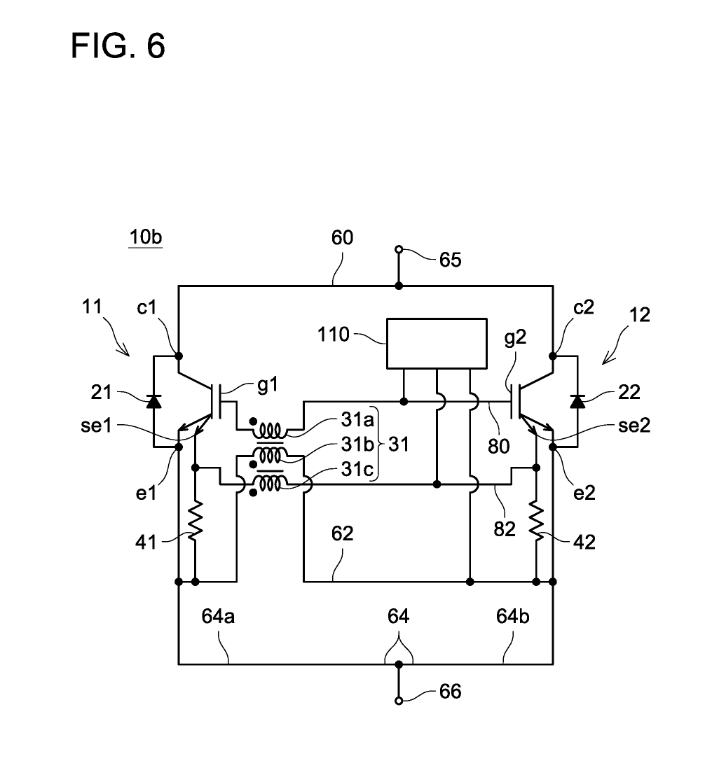

Next, with reference to FIG. 6, a switching circuit 10b of a third embodiment will be described. The switching circuit 10b differs from the switching circuit 10a of the second embodiment in that the switching circuit 10b does not include the second common-mode choke coil 32. Moreover, in the switching circuit 10b, the first common-mode choke coil 31 further includes a fifth coil 31c. In other words, the first common-mode choke coil 31 has a structure in which the three coils 31a to 31c are wound around one core.

The fifth coil 31c is interposed on the sense wiring 82 between the driving circuit 110 and the sense emitter terminal sel. The first common-mode choke coil 31 is configured such that a direction passing through the fifth coil 31c from the driving circuit 110 toward the sense emitter terminal se1 and the direction passing through the second coil 31b from the driving circuit 110 toward the emitter terminal el are common mode. The first common-mode choke coil 31 is configured such that the first coil 31a, the second coil 31b, and the fifth coil 31c are of subtractive polarity relative to one another.

The switching circuit 10a of the second embodiment includes the two common-mode choke coils 31, 32. Therefore, the switching circuit 10a has a relatively large size. Moreover, insertion of the two common-mode choke coils requires four wirings. In the switching circuit 10b in the present embodiment, however, the one common-mode choke coil 31 is configured to include the three coils 31a, 31b, and 31c. When the switching element is charged/discharged, the gate current flows through the coils 31a, 31b in the differential mode, so high-speed switching is achieved. When an imbalance occurs between the main currents, currents (that correspond to the currents Ia1, Ia2 in FIG. 3) flow through the coils 31a, 31b in the common mode, so the oscillation phenomenon is suppressed. When a sense current is to be detected, a current flows through the coils 31b, 31c in the differential mode, so the sense current can be detected accurately. When an imbalance occurs between sense currents, currents (that correspond to the currents Ia3, Ia1 in FIG. 4) flow through the coils 31b, 31c in the common mode, so the oscillation phenomenon is suppressed. As such, according to the switching circuit 10b in the present embodiment, one common-mode choke coil can suppress the oscillation phenomenon resulting from an imbalance between main currents and an imbalance between sense currents. Moreover, according to this configuration, the switching circuit can be miniaturized.

### Fourth Embodiment

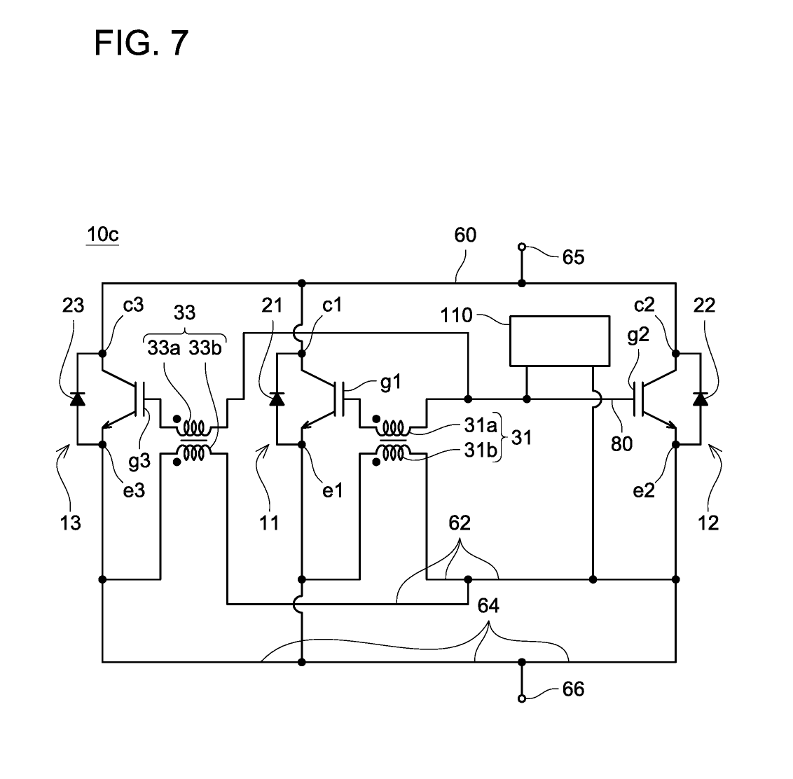

Next, with reference to FIG. 7, a switching circuit 10c of a fourth embodiment will be described. The switching circuit 10c differs from the switching circuit 10 of the first embodiment in that the switching circuit 10c further includes a third switching element 13 and a third common-mode choke coil 33.

The third switching element 13 includes a collector terminal c3, an emitter terminal e3, and a gate terminal g3. The collector terminal c3 is connected to the high potential wiring 60. In other words, the collector terminal c3 is connected to the collector terminal c1 and the collector terminal c2. The emitter terminal e3 is connected to the first low potential wiring 62 and the second low potential wiring 64. In other words, the emitter terminal e3 is connected to the emitter terminal e1 and the emitter terminal e2. Accordingly, the third switching element 13 is connected in parallel to the first switching element 11 and the second switching element 12. The gate terminal g3 is connected to the gate wiring 80. A potential of the gate terminal g3 is controlled by the driving circuit 110. A diode 23 is connected in inverse parallel to the third switching element 13. In other words, the diode 23 has its anode connected to the emitter terminal e3, and its cathode connected to the collector terminal c3.

The third common-mode choke coil 33 includes a sixth coil 33a and a seventh coil 33b. The sixth coil 33a is interposed on the gate wiring 80 between the driving circuit 110 and the gate terminal g3. The seventh coil 33b is interposed on the first low potential wiring 62 between the driving circuit 110 and the emitter terminal e3. The third common-mode choke coil 33 is configured such that a direction passing through the sixth coil 33a from the driving circuit 110 toward the gate terminal g3 and a direction passing through the seventh coil 33b from the driving circuit 110 toward the emitter terminal e3 are common mode. The third common-mode choke coil 33 is configured such that the sixth coil 33a and the seventh coil 33b are of subtractive polarity.

In the switching circuit 10c in the present embodiment, since the three switching elements are connected in parallel, an operation with a large current is allowed. Moreover, since the third common-mode choke coil 33 is provided, even if an imbalance occurs between a current of the third switching element 13 and a current of another switching element, the oscillation phenomenon can be suppressed. As such, in the switching circuit 10c, the oscillation phenomenon can be suppressed between every two of the first switching element 11, the second switching element 12, and the third switching element 13.

In the switching circuits of the first to fourth embodiments mentioned above, no common-mode choke coil is provided on wirings (the gate wiring 80, the first low potential wiring 62, and the sense wiring 82) between the second switching element 12 and the driving circuit 110. However, a common-mode choke coil may be provided on the wirings. It should be noted that providing no common-mode choke coil on the wirings between the second switching element 12 and the driving circuit 110 can miniaturize the switching circuit.

Moreover, in the switching circuits of the embodiments mentioned above, two or three switching elements are connected in parallel. However, the technology disclosed herein may also be applied to a switching circuit that includes four or more switching elements connected in parallel. If a switching circuit includes N switching elements connected in parallel, provision of N−1 (or N) common-mode choke coils can suppress oscillations between every two of the switching elements as in the embodiments mentioned above.

Moreover, in the switching circuits of the embodiments mentioned above, an IGBT in which a current flows from its collector to emitter is used as each of the switching elements. However, the technology disclosed herein may also be applied to other switching elements (n-channel type MOSFET, p-channel type MOSFET, and the like).

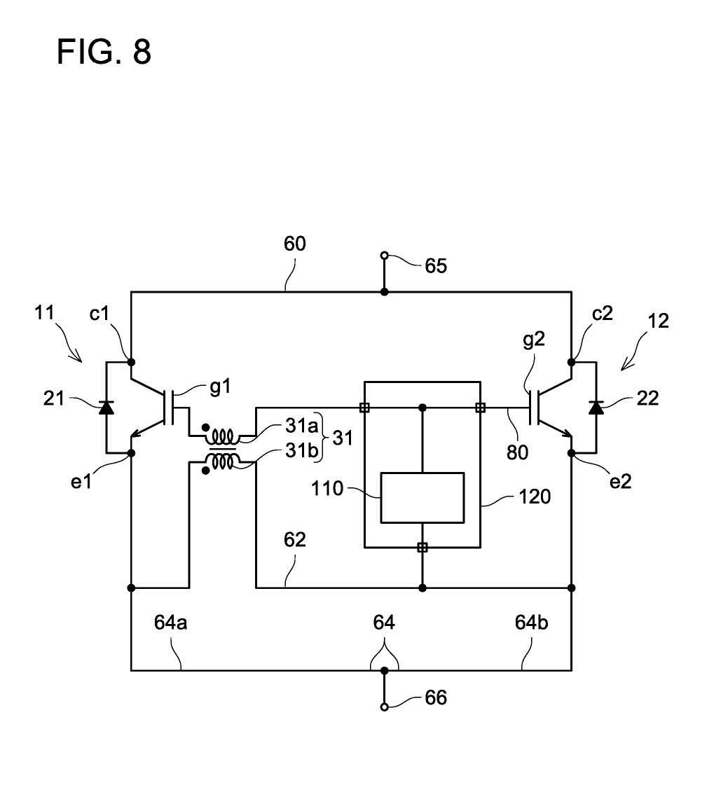

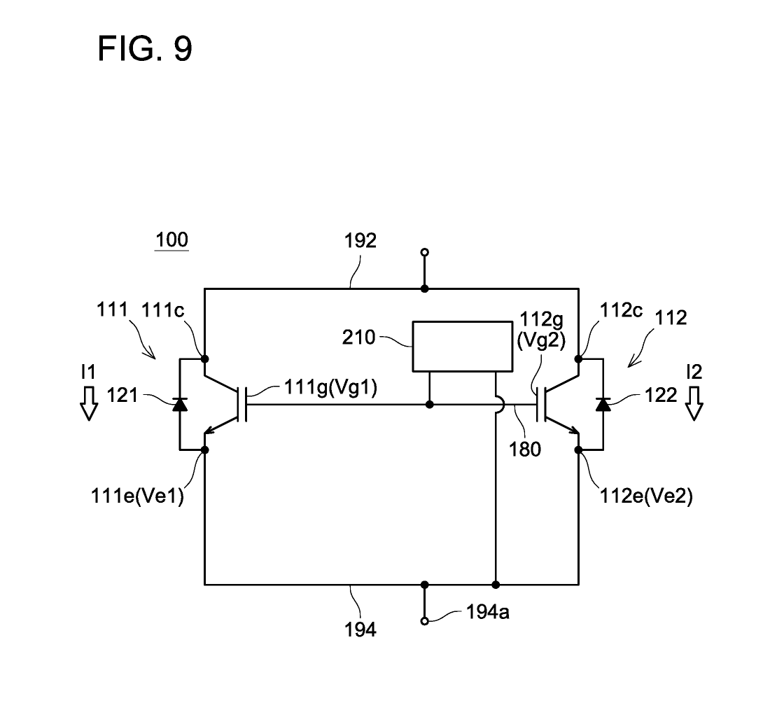

Moreover, in the embodiments mentioned above, the gate wiring 80 is provided outside the driving circuit 110. However, as shown in FIG. 8, the driving circuit 110 may be built in an IC 120, and a wiring inside the IC 120 may constitute a portion of the gate wiring 80.

(Correspondence Relationships)

The first low potential wiring 62 is an example of a low potential wiring. The collector terminal c1 is an example of a first high potential terminal. The emitter terminal e1 is an example of a first low potential terminal. The gate terminal g1 is an example of a first gate terminal. The collector terminal c2 is an example of a second high potential terminal. The emitter terminal e2 is an example of a second low potential terminal. The gate terminal g2 is an example of a second gate terminal. The sense emitter terminal se1 is an example of a first sense terminal. The sense emitter terminal se2 is an example of a second sense terminal. The current sense resistor 41 is an example of a first resistor. The current sense resistor 42 is an example of a second resistor. The collector terminal c3 is an example of a third high potential terminal. The emitter terminal e3 is an example of a third low potential terminal. The gate terminal g3 is an example of a third gate terminal.

Some of the features characteristic to the technology disclosed herein will be listed below. It should be noted that the respective technical elements are independent of one another, and are useful solely or in combinations.

In a configuration disclosed herein as an example, the first switching element may further include a first sense terminal through which a current smaller than a main current of the first switching element flowing through the first low potential terminal flows. The second switching element may further include a second sense terminal through which a current smaller than a main current of the second switching element flowing through the second low potential terminal flows. The switching circuit may further comprise: a sense wiring connecting the first sense terminal and the second sense terminal; a first resistor including one end connected to the first sense terminal and the other end connected to the low potential wiring; a second resistor including one end connected to the second sense terminal and the other end connected to the low potential wiring; and a second common-mode choke coil including a third coil and a fourth coil. The driving circuit may be connected to the sense wiring. The third coil may be interposed on the sense wiring between the driving circuit and the first sense terminal, and the fourth coil may be connected in parallel to the second coil between the driving circuit and the first low potential terminal. The second common-mode choke coil may be configured such that a direction passing through the third coil from the driving circuit toward the first sense terminal and a direction passing through the fourth coil from the driving circuit toward the first low potential terminal are common mode.

According to such a configuration, a current that flows through the first switching element can be detected based on a value of a current that flows through the first sense terminal (i.e., a potential difference across the first resistor). Moreover, a current that flows through the second switching element can be detected based on a value of a current that flows through the second sense terminal (i.e., a potential difference across the second resistor). Moreover, the second common-mode choke coil is configured such that the direction passing through the third coil from the driving circuit toward the first sense terminal and the direction passing through the fourth coil from the driving circuit toward the first low potential terminal are common mode, and thus, even if an imbalance occurs between the currents that flow through the first and second sense terminals, the second common-mode choke coil can suppress the oscillation phenomenon.

In a configuration disclosed herein as an example, the first switching element may further include a first sense terminal through which a current smaller than a main current of the first switching element flowing through the first low potential terminal flows. The second switching element may further include a second sense terminal through which a current smaller than a main current of the second switching element flowing through the second low potential terminal flows. The switching circuit may further comprise: a sense wiring connecting the first sense terminal and the second sense terminal; a first resistor including one end connected to the first sense terminal and the other end connected to the low potential wiring; and a second resistor including one end connected to the second sense terminal and the other end connected to the low potential wiring. The driving circuit may be connected to the sense wiring. The first common-mode choke coil may further include a fifth coil. The fifth coil may be interposed on the sense wiring between the driving circuit and the first sense terminal. The first common-mode choke coil may be configured such that a direction passing through the fifth coil from the driving circuit toward the first sense terminal and the direction passing through the second coil from the driving circuit toward the first low potential terminal are common mode.

According to such a configuration, a current that flows through the first switching element can be detected based on a value of a current that flows through the first sense terminal (i.e., a potential difference across the first resistor). Moreover, a current that flows through the second switching element can be detected based on a value of a current that flows through the second sense terminal (i.e., a potential difference across the second resistor). Moreover, the first common-mode choke coil is configured such that the direction passing through the fifth coil from the driving circuit toward the first sense terminal and the direction passing through the second coil from the driving circuit toward the first low potential terminal are common mode, and thus, even if an imbalance occurs between the currents that flow through the first and second sense terminals, the second common-mode choke coil can suppress the oscillation phenomenon. Moreover, according to this configuration, the switching circuit can be miniaturized.

In a configuration disclosed herein as an example, a switching circuit may further comprise: a third switching element including a third high potential terminal connected to the high potential wiring, a third low potential terminal connected to the low potential wiring, and a third gate terminal connected to the gate wiring; and a third common-mode choke coil including a sixth coil and a seventh coil. The driving circuit may be configured to control a potential of the third gate terminal. The sixth coil may be interposed on the gate wiring between the driving circuit and the third gate terminal, and the seventh coil may be interposed on the low potential wiring between the driving circuit and the third low potential terminal. The third common-mode choke coil may be configured such that a direction passing through the sixth coil from the driving circuit toward the third gate terminal and a direction passing through the seventh coil from the driving circuit toward the third low potential terminal are common mode.

According to such a configuration, even if an imbalance occurs between a current of the third switching element and a current of another switching element, the oscillation phenomenon can be suppressed suitably. Moreover, since a current with a total value of current-carrying capacities of the first, second, and third switching elements is allowed to flow, a large current is allowed to flow.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A switching circuit comprising:
a first switching element including a first high potential terminal, a first low potential terminal, and a first gate terminal;
a second switching element including a second high potential terminal, a second low potential terminal, and a second gate terminal;
a high potential wiring connecting the first high potential terminal and the second high potential terminal;
a low potential wiring connecting the first low potential terminal and the second low potential terminal;
a gate wiring connecting the first gate terminal and the second gate terminal;
a driving circuit connected to the low potential wiring and the gate wiring, and configured to control a potential of the first gate terminal and a potential of the second gate terminal; and
a first common-mode choke coil including a first coil and a second coil, wherein
the first coil is interposed on the gate wiring between the driving circuit and the first gate terminal,
the second coil is interposed on the low potential wiring between the driving circuit and the first low potential terminal, and
the first common-mode choke coil is configured such that a direction passing through the first coil from the driving circuit toward the first gate terminal and a direction passing through the second coil from the driving circuit toward the first low potential terminal are common mode.

2. The switching circuit of claim 1, wherein
the first switching element further includes a first sense terminal through which a current smaller than a main current of the first switching element flowing through the first low potential terminal flows,
the second switching element further includes a second sense terminal through which a current smaller than a main current of the second switching element flowing through the second low potential terminal flows,
the switching circuit further comprises:
a sense wiring connecting the first sense terminal and the second sense terminal;
a first resistor including one end connected to the first sense terminal and the other end connected to the low potential wiring;
a second resistor including one end connected to the second sense terminal and the other end connected to the low potential wiring; and
a second common-mode choke coil including a third coil and a fourth coil, wherein
the driving circuit is connected to the sense wiring,
the third coil is interposed on the sense wiring between the driving circuit and the first sense terminal,
the fourth coil is connected in parallel to the second coil between the driving circuit and the first low potential terminal, and
the second common-mode choke coil is configured such that a direction passing through the third coil from the driving circuit toward the first sense terminal and a direction passing through the fourth coil from the driving circuit toward the first low potential terminal are common mode.

3. The switching circuit of claim 1, wherein
the first switching element further includes a first sense terminal through which a current smaller than a main current of the first switching element flowing through the first low potential terminal flows,
the second switching element further includes a second sense terminal through which a current smaller than a main current of the second switching element flowing through the second low potential terminal flows,
the switching circuit further comprises:
a sense wiring connecting the first sense terminal and the second sense terminal;
a first resistor including one end connected to the first sense terminal and the other end connected to the low potential wiring; and
a second resistor including one end connected to the second sense terminal and the other end connected to the low potential wiring, wherein
the driving circuit is connected to the sense wiring,
the first common-mode choke coil further includes a fifth coil,
the fifth coil is interposed on the sense wiring between the driving circuit and the first sense terminal, and
the first common-mode choke coil is configured such that a direction passing through the fifth coil from the driving circuit toward the first sense terminal and the direction passing through the second coil from the driving circuit toward the first low potential terminal are common mode.

4. The switching circuit of claim 1, further comprising:
a third switching element including a third high potential terminal connected to the high potential wiring, a third low potential terminal connected to the low potential wiring, and a third gate terminal connected to the gate wiring; and
a third common-mode choke coil including a sixth coil and a seventh coil, wherein
the driving circuit is configured to control a potential of the third gate terminal,
the sixth coil is interposed on the gate wiring between the driving circuit and the third gate terminal,
the seventh coil is interposed on the low potential wiring between the driving circuit and the third low potential terminal, and
the third common-mode choke coil is configured such that a direction passing through the sixth coil from the driving circuit toward the third gate terminal and a direction passing through the seventh coil from the driving circuit toward the third low potential terminal are common mode.
